(19) United States
(12) Patent Application Publication
(10) Pub. No.: US 2006/0086961 A1
(43) Pub. Date: Apr. 27, 2006

(54) Semiconductor device having a stacked capacitor

(75) Inventors: Shinpei Iijima, Tokyo (JP); Keiji Kuroki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/253,628

(22) Filed: Oct. 20, 2005

(30) Foreign Application Priority Data
Oct. 21, 2004 (JP) 2004-306717

(51) Int. Cl. H01L 27/108

(52) U.S. Cl. 257/303

(57) ABSTRACT

A capacitor formed in a deep-hole has a bottom electrode, a capacitor insulator film and a top electrode. The bottom electrode includes a sidewall conductive film formed on the sidewall of a top portion of the deep-hole, and an inner conductive film formed on the sidewall conductive film and the sidewall and bottom of the through-hole. The inner conductive film is in contact with the underlying contact plug.

### BACKGROUND OF THE INVENTION

(a) Field of the Invention

The present invention relates to a semiconductor device having a stacked capacitor and, more particularly, to the structure of a stacked capacitor formed in a deep-hole. The present invention also relates to a method for manufacturing such a semiconductor device.

(b) Description of the Related Art

Recent development of semiconductor devices increases the performance thereof and decreases the dimensions thereof. A DRAM (dynamic random access memory) device now on the market has a giga-bit-order capacity with a minimum design rule of 110 nm. The next-generation DRAM device may have a minimum design rule of 90 nm or smaller. Along the reduction of the dimensions for the DRAM device, the dimensions of the cell capacitor used as the principal component thereof are inevitably reduced. This makes it difficult for the capacitor to have the specified capacitance for assuring the storage performance.

Among other stacked capacitors, a so-called deep-hole capacitor having a bottom electrode formed on a sidewall of a deep-hole has a smaller occupied area and yet a larger capacity, the deep-hole being formed within a thick insulator film. In an example, the deep-hole capacitor has a bottom electrode formed within an insulator film having a thickness of about 2000 nm, wherein the bottom electrode has a HSG (hemispherical silicon grain) structure on the surface thereof. The HSG structure increases the capacitance per unit area of the bottom electrode. The thickness of the bottom electrode having the HSG structure is about 80 nm, as measured between the sidewall of the deep-hole and the top surface of the HSG

The deep-hole has a shape of an ellipse, that is close to a circle, in a horizontal section thereof. If the ellipse has a minor axis of 250 nm for example, since the HSG structure assumes a total thickness of 160 nm on both the sidewalls, the effective width of the deep-hole allowed for forming the capacitor including a capacitor insulator film and a top electrode is only about 90nm. If the capacitor insulator film formed on the bottom electrode has a reduced thickness, a leakage current will flow between the bottom electrode and the top electrode, thereby degrading the storage performance of the memory cell. Thus, it is important to assure a sufficient space for the capacitor insulator film as well as the top electrode.

If a width of 90 nm, for example, is ensured within the deep-hole after forming the bottom electrode, this width will be sufficient for forming the capacitor insulator film and the top electrode in the current fabrication technique. However, the width of 90 nm cannot be ensured in the case of capacitor having the HSG structure if the deep-hole has a minor axis of around 200 nm, for example.

Thus, a structure other than the HSG structure is desired in the bottom electrode for increasing the effective surface area for the bottom electrode. For example, if the deep-hole has a depth larger than 2000 nm, for example, as large as 3000 nm, the effective surface area may be assured for the bottom electrode. However, such a large depth of the deep-hole incurs a problem of “bowing shape” during forming the deep-hole by an anisotropic etching process. The “bowing shape” is incurred by the etching process wherein the anisotropic etching removes an undesired portion of the side surface of the deep-hole to increase the diameter at a specific depth of the deep-hole. The problem of the bowing shape will be described hereinafter.

FIGS. 7A to 7J show consecutive steps of a conventional fabrication process for forming a deep-hole stacked capacitor in a semiconductor device. First, source/drain diffused regions are formed on a surface area of a silicon substrate, followed by forming gate insulating films and gate electrodes thereon. Subsequently, a first interlevel dielectric film overlying the gate electrodes is formed by deposition.

Thereafter, a second interlevel dielectric film 201 is formed on the first interlevel dielectric film, followed by forming contact-holes 202a in the first and second interlevel dielectric films and filling the contact-holes 202a with contact plugs 202. Subsequently, a silicon nitride film 203 and a 3000-nm-thick interlevel dielectric film 204 made of silicon dioxide are consecutively deposited thereon. Another silicon film having a thickness of 500 nm is deposited thereon using a CVD technique, followed by patterning thereof using a photolithographic and etching technique to thereby obtain a hard mask 205 having therein an elliptical opening 205a having a minor axis of 200 nm. The resultant structure is shown in FIG. 7A.

Thereafter, the interlevel dielectric film 204 is patterned by dry-etching using the hard mask 205 and a mixed gas including C₅F₈ and O₂ at an ambient pressure of 100 mTorr and a plasma power of 1200 watts. Ar and/or CHF₃ may be added to the mixed gas. FIG. 7B shows the dry etching when the etching step proceeds to a depth of about 1000 nm. Up to this step, a bowing shape does not appear, and thus the sidewall of the deep-hole is substantially perpendicular to the substrate surface. The edge 211 of the hard mask 205 is etched to some extent and thus has a slope. FIG. 7C shows the dry etching step when the etching step proceeds to a depth of about 2000 nm. The edge of the hard mask 205 is further etched, and a bowing shape 212 appears on the sidewall of the deep-holes 206.

The dry etching of the silicon dioxide constituting the interlevel dielectric film proceeds to cut the bonds between Si atoms and O atoms in the silicon dioxide, and react the Si atoms and F atoms together to prepare volatile SiF₄. F ions constitute the main etchant contributing the reaction. The F ions are accelerated by a potential difference applied by a self-bias of the plasma or applied intentionally between the substrate and the plasma, impinging upon the substrate basically normal to the surface thereof. However, if the hard mask 205 has a sloped edge 211 on the surface thereof, the number of F ions impinging on the substrate surface in a sloped direction will be increased due to the affection by the sloped edge. The bowing shape is considered to be incurred by the F ions obliquely impinging upon the vicinity of top openings of the deep-holes 206.

The problem of the bowing shape can be neglected in the conventional DRAM device wherein the deep-holes are not especially deep. However, the problem becomes serious along with an increase in the depth of the deep-holes and a decrease in the width thereof. FIG. 7D shows the deep-holes 206 after the dry etching step is completed to expose the silicon nitride film 203 therethrough. The bowing shape 212 appearing on the sidewall of the deep-holes 206 generates a structure wherein the minimum thickness L2 of the separation wall between adjacent deep-holes is smaller than the design thickness L1 of the separation wall defined in the pattern of the hard mask 205.

Thereafter, as shown in FIG. 7E, a polysilicon film 207a is deposited using a CVD technique to a thickness of 40 nm. The resultant polysilicon film 207a has a shape conforming to the bowing shape of the deep-holes 206. A filling material 208 fills the internal of the deep-holes 206 in the next step shown in FIG. 7E

Thereafter, the hard mask 205 and the portion of the polysilicon film 207a outside the deep-holes are removed by a CMP or dry-etching process, as shown in FIG. 7F, thereby leaving the portion of the polysilicon film 207a inside the deep-holes 206 to form bottom electrodes 207. If the dry-etching process is used herein, the etching step may use an etching gas including Cl₂ and O₂ as main components thereof, a gas pressure of 10 mTorr, and a plasma power of 100 watts. A HBr gas may be added to the etching gas.

Thereafter, as shown in FIG. 7G, the filling material 208 is removed from the deep-holes 206 as by oxygen plasma. Subsequently, the top portion of the interlevel dielectric film 204 is removed by a wet etching using a hydrofluoric-acid-containing solution, thereby allowing the bottom electrodes 207 to protrude from the top of the interlevel dielectric film 204, as shown in FIG. 7H. This structure of the bottom electrodes 207 is referred to as a pseudo-crown structure. In an alternative structure, the interlevel dielectric film 204 is not etched, allowing the bottom electrode to has a HSG structure as described before. The HSG structure should be associated with a structure wherein the polysilicon film is replaced by an amorphous silicon film.

Thereafter, as shown in FIG. 71, a 9-nm-thick insulator film 209 made of tantalum oxide is deposited on the exposed bottom electrodes 207 by a CVD technique. The deposition of the tantalum oxide film 209 is followed by a heat treatment thereof in an oxidizing atmosphere, for reduction of a leakage current in the resultant capacitor. Thereafter, as shown in FIG. 7J, a titanium nitride film 210 is deposited on the entire surface of the insulator film 209 by a CVD process, followed by forming top electrodes 210 to thereby obtain capacitors each including a bottom electrode 207, a capacitor insulator film 209 and a top electrode 210. In the resultant capacitor, the bowing shape incurs a plurality of air gaps 213 within the internal or external of the deep-holes 206.

The bowing shape in the deep-holes as described above makes it difficult to reduce dimensions of the semiconductor device because the thickness of the separation wall between adjacent deep-holes is smaller than the design thickness and thus the design thickness must have a margin corresponding to the reduction of the thickness of the separation wall.

In addition, the plurality of air gaps 213 generated in the internal or external of the deep-holes reduces the mechanical strength of the bottom electrodes 207. Thus, the bottom electrodes 207 may be damaged by the stress applied by the top electrode 210, an insulator film formed above the capacitor, or a mold resin for packaging therein the DRAM device. Thus, the resultant DRAM device may have a large leakage current in the cell capacitors due to the damage of the bottom electrodes 207, whereby the product yield of the DRAM devices may be reduced.

Patent Publication JP-A-2002-110647 describes a technique for suppression of the bowing shape on the sidewall of deep-holes by adjusting process conditions for the dry etching to form the deep-holes.

In the described technique, the etching capability and deposition capability of the plasma are alternately adjusted by controlling the plasma conditions to thereby suppress generation of the bowing shape. However, it is in fact difficult to control the plasma conditions within the deep-holes. In this respect, formation of the deep-holes itself may be difficult in the process.

### SUMMARY OF THE INVENTION

In view of the above problems in the conventional techniques, it is an object of the present invention to provide a semiconductor device wherein formation of the bowing shape is suppressed on the sidewall of the deep-holes.

It is another object of the present invention to provide a method for manufacturing such a semiconductor device.

The present invention provides, in a first aspect thereof, a semiconductor device including: a semiconductor substrate; an insulator film overlying the semiconductor substrate and having a deep-hole therein; a capacitor including a cylindrical first electrode received in the deep-hole and having a cylindrical sidewall and a bottom portion, a capacitor insulator film formed on the first electrode, and a second electrode opposing the first electrode; and a contact plug connected to the bottom portion of the first electrode, wherein: the first electrode includes a plurality of conductive layers including a first conductive layer and a second conductive layer covering the first conductive layer, the second conductive layer configuring the bottom portion in contact with the contact plug.

The present invention provides, in a second aspect thereof, a semiconductor device including: a semiconductor substrate; an insulator film overlying the semiconductor substrate and having a deep-hole therein; and a contact plug received in the deep-hole and including a plurality of conductive layers, the conductive layers including a first cylindrical conductive layer in contact with a sidewall of the deep-hole and a second conductive layer received in the cylindrical first conductive layer, the second conductive layer configuring a bottom portion of the contact plug.

The present invention provides, in a third aspect thereof, a method for manufacturing a semiconductor device including the steps of: forming a first insulator film overlying a semiconductor substrate; forming a contact plug penetrating the first insulator film; forming a second insulator film on the first insulator film and the contact plug; etching the second insulator film to form therein a first hole aligned with the contact plug, the first hole having a depth smaller than a thickness of the second insulator film; forming a first conductive film on a sidewall of the first hole; etching the second insulator film at a bottom of the first hole by using the first conductive film as a mask to form a second hole extending from the first hole, the second hole exposing therethrough a top of the contact plug; depositing a second conductive film on the first conductive film, a sidewall of the second hole and the top of the contact plug, to thereby form a first electrode having a cylindrical sidewall and a bottom portion; forming a capacitor insulator film on the first electrode; and forming a second electrode on the insulator film to oppose the first electrode.

The present invention provides, in a fourth aspect thereof, a method for manufacturing a semiconductor device including the steps of: forming an interconnect pattern overlying a substrate; forming an insulator film on the interconnect pattern; etching the insulator film to form therein a first hole having a depth smaller than a thickness of the first insulator film; forming a cylindrical first conductive film on a sidewall of the first hole; etching the insulator film at a bottom of the first hole by using the first conductive film as a mask to form a second hole extending from the first hole, the second hole exposing therethrough the interconnect pattern; and forming a second conductive film within the cylindrical first conductive film and the second hole to form a contact plug in contact with the interconnect pattern.

In accordance with the semiconductor device of the first aspect of the present invention and the semiconductor device manufactured by the method of the third aspect of the present invention, the first electrode having a plurality of conductive patterns has a higher mechanical strength without a bowing shape, whereby a higher capacitance for the capacitor and a higher integration density for the semiconductor device can be achieved.

In accordance with the semiconductor device of the second aspect of the present invention and the semiconductor device manufactured by the method of the fourth aspect of the present invention, the contact plug has a higher mechanical strength without incurring a bowing shape during fabrication of the semiconductor device, whereby both a higher mechanical strength and a higher integration density can be achieved in the semiconductor device.

The above and other objects, features and advantages of the present invention will be more apparent from the following description, referring to the accompanying drawings.

### BRIEF DESCRIPTION OF THE DRAWINGS

FIG. 1 is a sectional view of a semiconductor device according to a first embodiment of the present invention.

FIGS. 2A to 2J are sectional views of the semiconductor device of FIG. 1, showing consecutive steps of a fabrication process according to a second embodiment of the present invention.

FIGS. 3A to 3D are sectional views of a semiconductor device, showing consecutive steps of the fabrication process thereof according to a first modification of the fabrication process of FIGS. 2A to 2J.

FIGS. 4A and 4B are sectional views of a semiconductor device, showing consecutive steps of the fabrication process thereof according to a second modification of the fabrication process of FIGS. 2A to 2J.

FIGS. 5A to 5J are sectional views of a semiconductor device, showing consecutive steps of a fabrication process according to a third embodiment of the present invention.

FIG. 6 is a sectional view of a semiconductor device according to a fourth embodiment of the present invention.

FIGS. 7A to 7J are sectional views of a semiconductor device, showing consecutive steps of a conventional fabrication process thereof.

### PREFERRED EMBODIMENT OF THE INVENTION

Now, the present invention is more specifically described with reference to accompanying drawings.

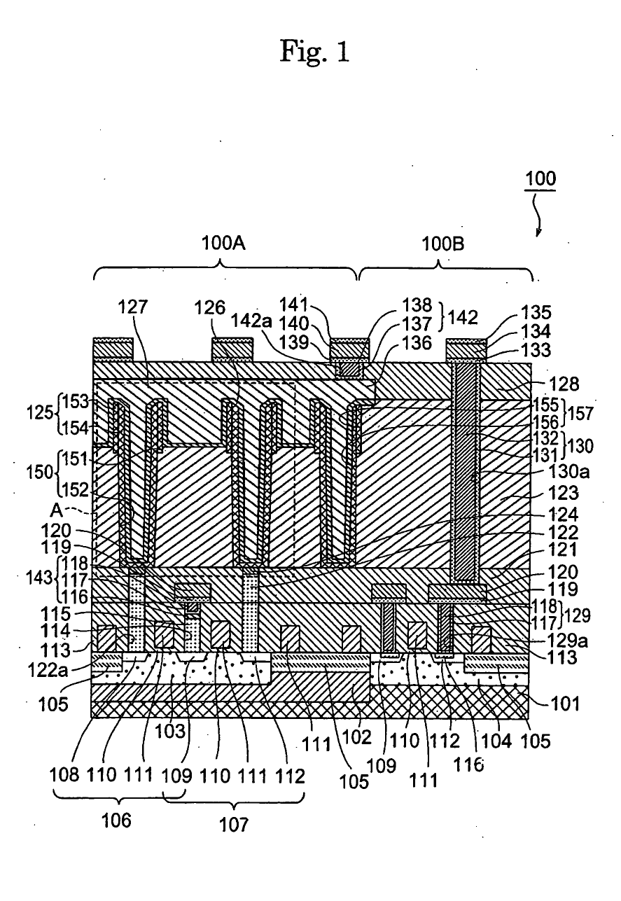

Referring to FIG. 1, a semiconductor device, generally designated by numeral 100, according to a first embodiment of the present invention configures a DRAM device. The DRAM device 100 includes a p-type silicon substrate 101 having therein an n-well 102 in a memory cell area 100A on the surface region of the silicon substrate 101, the n-well 102 receiving therein a first p-well 103 on the surface region of the n-well 102. The silicon substrate 101 also has a second p-well 104 in a peripheral circuit area 100B on the surface region of the silicon substrate 101. An isolation area 105 isolates the second p-well 104 from the first p-well 103.

Switching transistors 106 and 107 are formed to configure a memory cell in the memory cell area 100A. Transistor 106 includes a drain 108, a source 109 and a gate electrode 111 overlying the silicon substrate 101 with an intervention of a gate insulating film 110. Transistor 107 includes the source 109 in common with transistor 106, a drain 112 and a gate electrode 111. A first interlevel dielectric film 113 overlies the transistors 106 and 107 and the silicon substrate 101. The gate electrode 111 has a polycide structure including a polysilicon film and an overlying tungsten silicide film, or a polymetal structure including a polysilicon film and an overlying tungsten film.

The first interlevel dielectric film 113 has therein contact-holes 114 each filled with a polysilicon contact plug 115. On the first interlevel dielectric film 113 and contact plugs 115 is formed a bit line, which includes a tungsten nitride film 119 and a tungsten film 120. A bit contact 143 connects together the bit line and the polysilicon film 115. The bit contact 143 includes a titanium silicide film 116 in contact with the polysilicon film 115, a thin titanium nitride film 117, and a tungsten plug 118 filling the contact-hole 114 with an intervention of the thin titanium silicide 117. A second interlevel dielectric film 121 overlies the bit lines and the first interlevel dielectric film 113.

Contact-holes 122a penetrate the first and second interlevel dielectric films 113 and 121 to reach the drains 108 and 112 of the transistors. Each contact-hole 122a receives therein a silicon contact plug 122 and a metal silicide film 124 on top of the silicon contact plug 122.

On the second interlevel dielectric film 121 is formed a thick third interlevel dielectric film 123, which has a top surface lower in the memory cell area 100A than in the peripheral circuit area 100B. The third interlevel dielectric film 123 has therein deep-holes 150 each including first and second holes 151 and 152.

The first and second holes 151 and 152 are aligned to be coaxial and each has a cross-section of an ellipse, which is close to a circle. The first and second holes 151 and 152 have minor axis of 180 nm and 120 nm, respectively. As shown in FIG. 1, the deep-holes 150 each including the first and second holes 151 and 152 have no bowing shape.

The third interlevel dielectric film 123 has, in the vicinity of the periphery of the memory cell area 100A, a dummy deep-hole 157 including a first hole 155 and a second hole 156. The dummy deep-hole 157 is not aligned with any underlying contact plug or contact-hole.

A cylindrical sidewall conductive film 153 made of polysilicon is formed on the sidewall of the top portion of each of the deep-holes 150, and extends upward from the top portion of each of the deep-holes 150. An inner conductive film 154 made of polysilicon is formed on the inner surface of the sidewall conductive film 153, the sidewall of the middle and bottom portion of each of the deep-holes 150, and the bottom of each of the deep-holes 150. The sidewall conductive film 153 and the inner conductive film 154 configure a bottom electrode 125 of a capacitor, the inner conductive film 154 configuring a bottom portion of the bottom electrode 125 being in contact with the metal silicide plug 124. The vertical length of the bottom electrodes 125 is around 3000 nm. The dummy contact-hole 157 also receives therein a sidewall conductive film 153 and an inner conductive film 154 similar to those received in the deep-holes 150.

A thin dielectric film 126 configuring a capacitor insulator film is formed on the bottom electrode 125 and the third interlevel dielectric film 123 in the memory cell area 100A. A top electrode 127 is formed on the thin dielectric film 126 inside the deep-holes 150 and on the top of the third interlevel dielectric film 123, thereby opposing the bottom electrodes 125 with an intervention of the thin dielectric film 126. The top electrode 127 has a top surface higher than the top of the third interlevel dielectric film 123 within the peripheral circuit area 100B. Each bottom electrode 125, the thin dielectric film 126 and top electrode 127 configure a pseudo-crown capacitor. The material for the contact plug 122 is preferably selected depending on the material for the bottom electrodes 125, and may be different therefrom. For example, the material may be silicon or a metallic material.

The thin dielectric film 126 and the top electrode 127 extend from the memory cell area 100A toward the peripheral circuit area 100B, wherein the latter configures a lead interconnect 136.

A fourth interlevel dielectric film 128 is formed on the top electrode 127 and third interlevel dielectric film 123. The fourth interlevel dielectric film 128 has therein through-holes 142a, each of which receives therein a plug 142. The plug 142 includes a titanium nitride film 137 formed on the sidewall and bottom of the through-holes 142a, and a tungsten plug 138 filling the through-holes 142a with an intervention of the titanium nitride film 137.

On the second p-well 104 in the peripheral circuit area 100B, transistors are formed each including a source 109, drain 112, and a gate electrode 111 to configure the peripheral circuit. The first interlevel dielectric film 113 has therein contact-holes 129a each receiving therein a contact plug 129, which contacts the source 109 or drain 112. The contact plug 129 includes a titanium nitride film 117 and a tungsten plug 118. The surface portion of the source 109 and drain 112 includes titanium silicide 116.

On top of the contact plug 129 and first interlevel dielectric film 113 is formed a first-layer interconnect, which includes a tungsten nitride film 119 and an overlying tungsten film 120 and is covered with a second interlevel dielectric film 121.

A through-hole 130a is formed in the second interlevel dielectric film 121, third interlevel dielectric film 123 and fourth interlevel dielectric film 128, and receives therein a via plug 130 which contacts the top of the first-level interconnect. The via plug 130 includes a titanium nitride film 131 and a tungsten plug 132.

On top of the fourth interlevel dielectric film 128 and via plug 130 are formed second-level interconnects, each of which includes a titanium nitride film 133, an aluminum film 134 and a titanium nitride film 135. On top of the fourth interlevel dielectric film 128 and via plug 142 are formed third-level interconnects, each of which includes titanium nitride film 139, an aluminum film 140 and a titanium nitride film 141. The semiconductor device 100 has also other interlevel dielectric films, via plugs and interconnects which are generally used to configure a DRAM device.

In accordance with the DRAM device 100 of the present embodiment, the configuration of the bottom electrodes 125 having a vertical length as long as 3000 nm provides a larger capacitance for the capacitor. In addition, the vertical shape of the bottom electrodes 125 close to the design shape allows a smaller space margin between adjacent capacitors, thereby reducing the dimensions of the DRAM device. Further, since the internal or external of the cylindrical bottom electrodes 125 is free from an air gap, the bottom electrodes 125 have a larger mechanical strength.

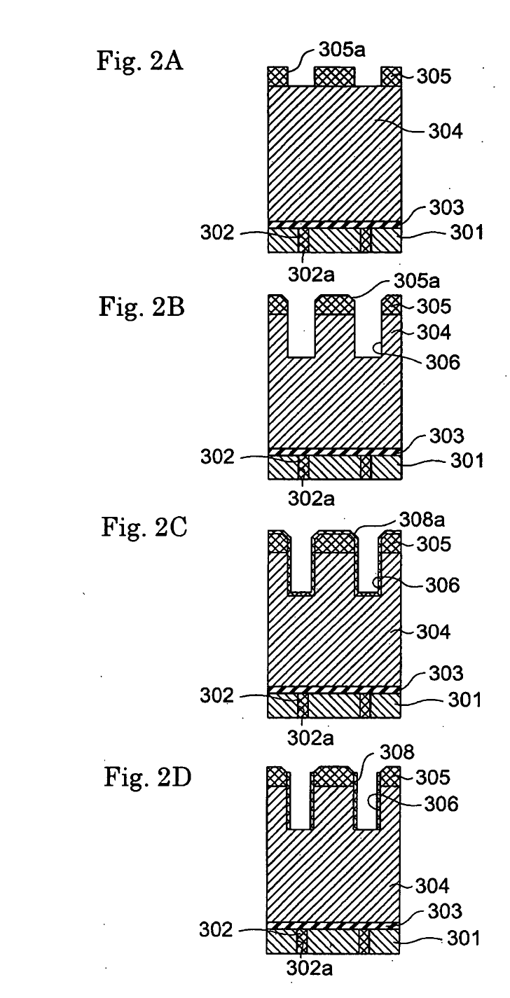

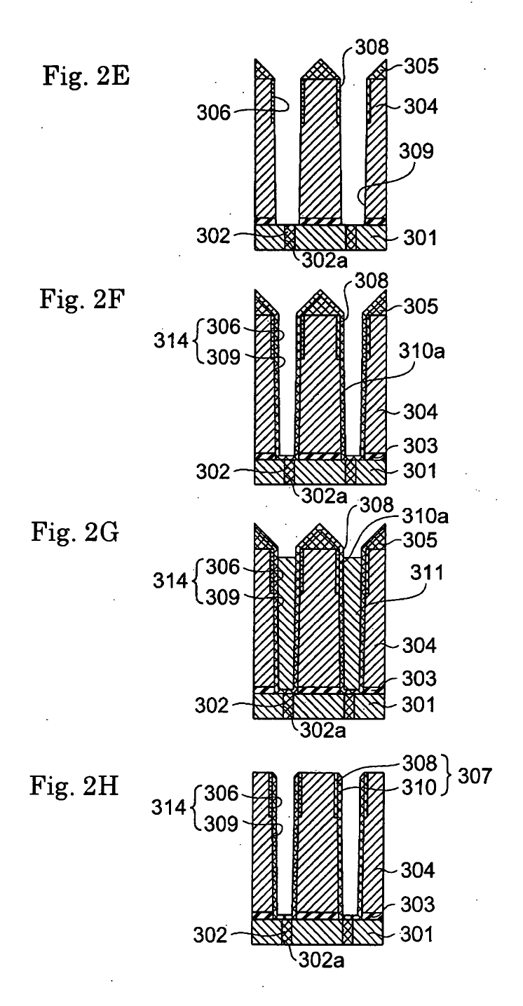

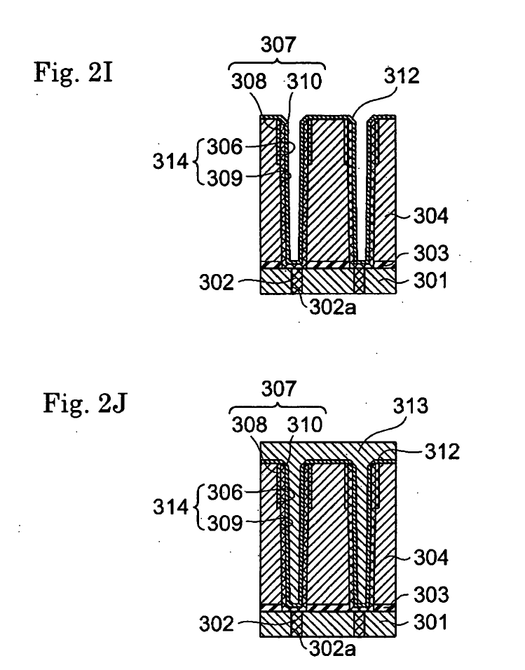

FIGS. 2A to 2J show consecutive steps of a fabrication process for the DRAM device of FIG. 1. These drawings show the portion encircled by a dotted line denoted by “A” in FIG. 1. Underlying transistors each including a source, a drain and a gate electrode is formed on a silicon substrate, followed by forming a first interlevel dielectric film on the transistors and the silicon substrate.

Thereafter, as shown in FIG. 2A, a second interlevel dielectric film 301 is formed on the first interlevel dielectric film, followed by forming contact-holes 302a in the second interlevel dielectric film 301. Thereafter, a polysilicon film is deposited on the second interlevel dielectric film 301 to fill the contact-holes 302a by using a CVD technique. The polysilicon film is doped with phosphorous during the deposition for increasing the conductivity thereof. The polysilicon outside the contact-holes 302a is then removed by a dry-etching or CMP (chemical-mechanical polishing) technique, thereby leaving contact plugs 302 in the contact-holes 302a. In an alternative, the polysilicon film may be replaced by an amorphous silicon film during the deposition, which is thereafter thermally treated to form polysilicon.

A 50-nm-thick silicon nitride film 303 is then deposited using a CVD technique. It should be noted that the contact plugs 302 may be formed after deposition of the silicon nitride film 303. Subsequently, a 3000-nm-thick third interlevel dielectric film 304 made of silicon dioxide is deposited using a CVD technique. A 500-nm-thick amorphous silicon film is then deposited using a CVD technique, followed by a heat treatment thereof to form a polysilicon film. The deposition of the amorphous film is preferable for the case of forming a hard mask because of the even surface of the amorphous silicon film, which achieves an accurately patterned edge.

Thereafter, the polysilicon film is patterned using photolithography and a dry etching technique, thereby forming a hard mask 305 having therein openings 305a. In the present embodiment, the openings 305a have a shape of ellipse close to a circle, the ellipse having a minor axis of 180 nm. The dry etching uses a chlorine-based gas such as a mixed gas including Cl₂, HBr and O₂, a gas pressure of 10 mTorr and a plasma power of 100 watts.

Thereafter, as shown in FIG. 2B, the third interlevel dielectric film 304 is etched by an anisotropic dry etching technique using the hard mask 305 as an etching mask, thereby forming first holes 306 having a depth of around 1000 nm. This small depth allows the first holes 306 to be free from the bowing shape on the sidewall thereof. The etching of the third interlevel dielectric film 304 made of silicon dioxide basically uses a fluorine-based gas and a higher plasma power, which effectively accelerates plasma ions. For example, this etching process uses a mixed gas including C₅F₈ and O₂, a gas pressure of 10 mTorr and a plasma power of 1500 watts.

A surface cleaning process is conducted, if desired, after the dry etching, and thereafter, a 20-nm-thick first silicon film 308a is deposited using a CVD technique, as shown in FIG. 2C. The first silicon film 308a is deposited using a silicon source gas including monosilane (SiH₄) or disilane (Si₂H₆) and an impurity source gas including phosphine (PH₃), these gases being decomposed by heat to deposit the silicon film 308a in an amorphous state. Although the first silicon film 308a may be deposited in the form of polysilicon, it is preferable to deposit the first silicon film 308a in the form of amorphous silicon because the polysilicon film has an uneven surface. As is well known in the art, a temperature below 530 degrees C. in a general CVD process allows the deposited silicon to assume an amorphous state, whereas a temperature above 600 degrees C. allows the deposited silicon to assume a polysilicon state.

Thereafter, as shown in FIG. 2D, a portion of the first silicon film 308a on the bottom of the first holes 306 is selectively removed using an anisotropic etching process, leaving sidewall conductive films 308 on the sidewall of the first holes 306. This dry etching may use a chlorine-based gas similar to the etching gas used for forming the hard mask 305.

Thereafter, by an anisotropic etching using the hard mask 305 and the sidewall conductive films 308 as a mask, the portion of the third interlevel dielectric film 304 exposed from the bottom of the first holes 306 is etched until the top of the contact plugs 302 is exposed therefrom. This anisotropic dry etching process provides deep-holes 314 each including the first hole 306 and a second hole 309 extending from the first hole 306, as shown in FIG. 2E. This dry etching uses conditions similar to those used for forming the first holes 306. Thereafter, the entire exposed surface is cleaned, and a natural oxide film having a thickness of around 1 nm and formed on the contact plugs 302 is removed using a hydrofluoric-acid-containing solution, followed by forming a 30-nm-thick second silicon film 310a by using a CVD technique, as shown in FIG. 2E Thereafter, as shown in FIG. 2G, a filling material such as photoresist is formed to fill the deep-holes 314. The filling process includes the steps of forming a photoresist film on the entire surface by coating, exposing the entire surface of the photoresist film to light by using a specific exposing condition, and developing the exposed photoresist film. Thereafter, the hard mask 305 and second silicon film 310a formed on the third interlevel dielectric film 304 outside the deep-holes 314 are removed by anisotropic dry etching, whereby the second silicon film 310a is configured to an inner conductive film 310 having a sidewall portion and a bottom portion. Thus, bottom electrodes 307 each including the sidewall conductive film 308 and the inner conductive film 310 are formed in the deep-holes 314. It should be noted that the removal of the hard mask 305 and the second silicon film 310a may be performed by a CMP process.

Thereafter, as shown in FIG. 2H, the filling material 311 is removed as by oxygen plasma, and a heat treatment is performed at a temperature of 750 degrees C. for a minute to crystallize the silicon in the bottom electrodes 307. It is to be noted that the heat treatment may be performed at another stage such as immediately after the deposition. In addition, a surface cleaning step may be performed prior to the heat treatment.

Thereafter, a natural oxide film grown on the bottom electrodes 307 up to a thickness of around 1 nm is removed using hydrofluoric acid. Thereafter, as shown in FIG. 2I, a 4-nm-thick dielectric film 312 made of aluminum oxide is formed on the entire surface of the memory cell area 100A by using a source gas including trimethyl-alcohol (TMA: Al(CH₃)₃) and ozone (O₃) at a ratio of 3:1, at a temperature of 400 degrees C. and a gas pressure of 1.5 Torr. This deposition uses a known step-deposition technique wherein charge and discharge of the TMA and charge and discharge of the ozone are alternately performed until the resultant dielectric film 312 has a desired thickness.

Thereafter, as shown in FIG. 2J, a top electrode 313 made of titanium nitride is deposited on the entire surface by using a source gas including TiCl₄ and NH₃ at a temperature of 500 degrees C. A tungsten film may be additionally formed thereon. Thus, capacitors each having a bottom electrode, capacitor insulator film and a top electrode are formed. Other known steps are then performed to complete the DRAM device.

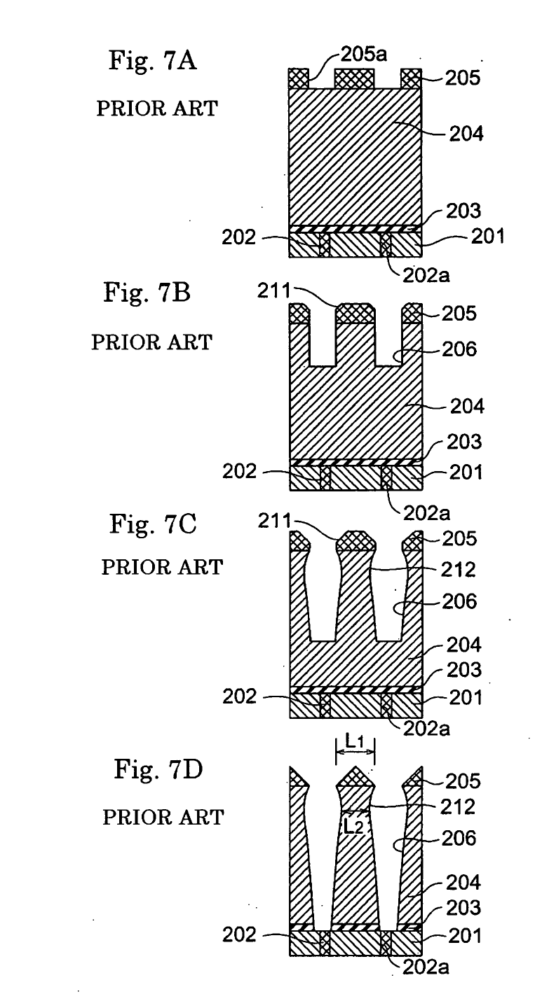

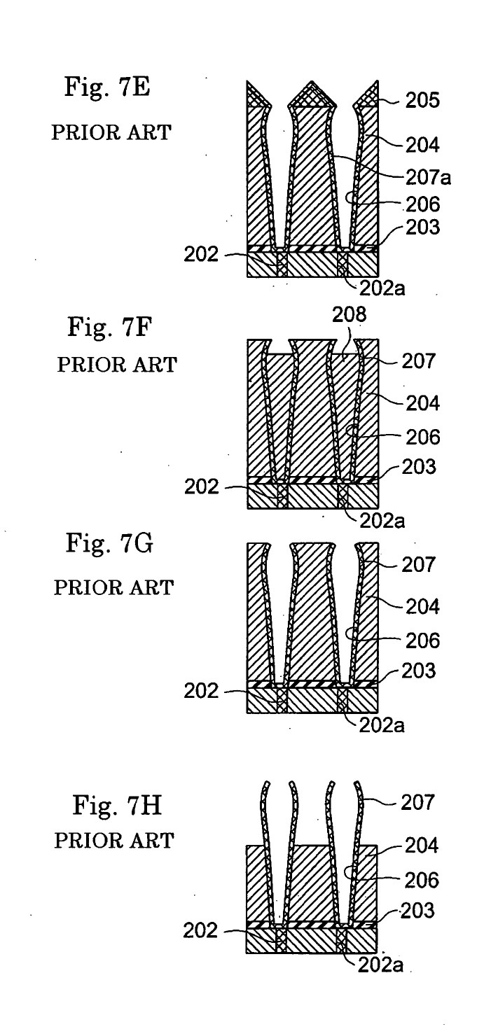

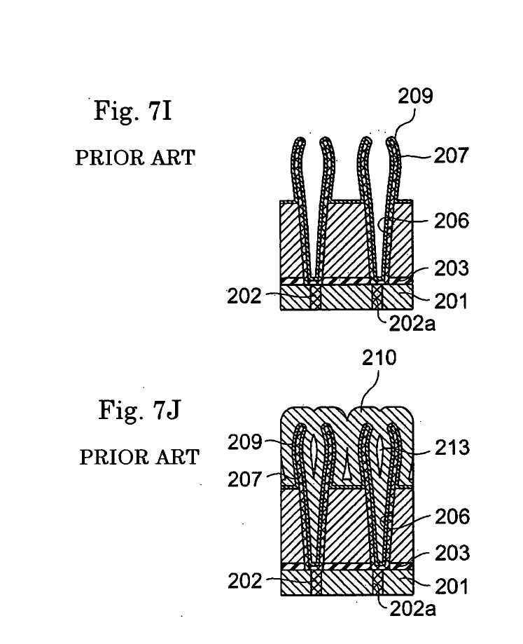

In the present embodiment, relatively shallow first holes 306 are formed which are free from the bowing shape, and then second holes 309 each extending from the first hole 306 are formed using the sidewall conductive film 308 as a mask, which is scarcely etched by the fluorine-based gas. Thus, even if the deep-holes 314 each including the first and second holes 306 and 309 have a depth of around 3000 nm, the deep-holes 314 are substantially free from the bowing shape. This allows the minimum thickness (L2 in FIG. 7D) of the separation wall can be close to the design thickness of the separation wall or the width (L1 in FIG. 7) of the hard mask 205. In other words, the deep-holes 314 each for forming therein a capacitor have a superior vertical sidewall. Thus, the resultant DRAM device has a larger capacitance for the cell capacitors and yet has reduced dimensions and a higher mechanical strength in the memory cells, thereby achieving a higher integration density and a higher reliability.

Although the dielectric film 312 has a single-layer structure including aluminum oxide having a dielectric constant of 9 in the above embodiment, the dielectric film 312 may have a two-layer structure such as including a hafnium oxide or tantalum oxide film and an underlying aluminum oxide film, or three-layer structure wherein an aluminum oxide film is sandwiched between a pair of hafnium oxide or tantalum oxide films. Such a structure allows the capacitor to have a higher capacitance because the dielectric constants of the hafnium oxide and tantalum oxide are around 20. The polysilicon film of the bottom electrode, which is obtained by heat treating an amorphous silicon film, may have a HSG structure so long as the deep-hole has a sufficient space therein.

The depth of the first holes 306 may be determined so that the first holes 306 are free from the bowing shape during etching of the third interlevel dielectric film. In some experimental cases, the bowing shape occurs at a critical aspect ratio of around 10 or above, the term “aspect ratio” being defined by a ratio of the depth to the minor axis of the hole. Thus, it is preferable that the first holes have an aspect ratio of around 8, which is well lower than the critical aspect ratio. For example, if the first holes 306 have a minor axis of 180 nm, the first holes 306 are allowed to have a depth of 1400 nm without incurring a bowing shape.

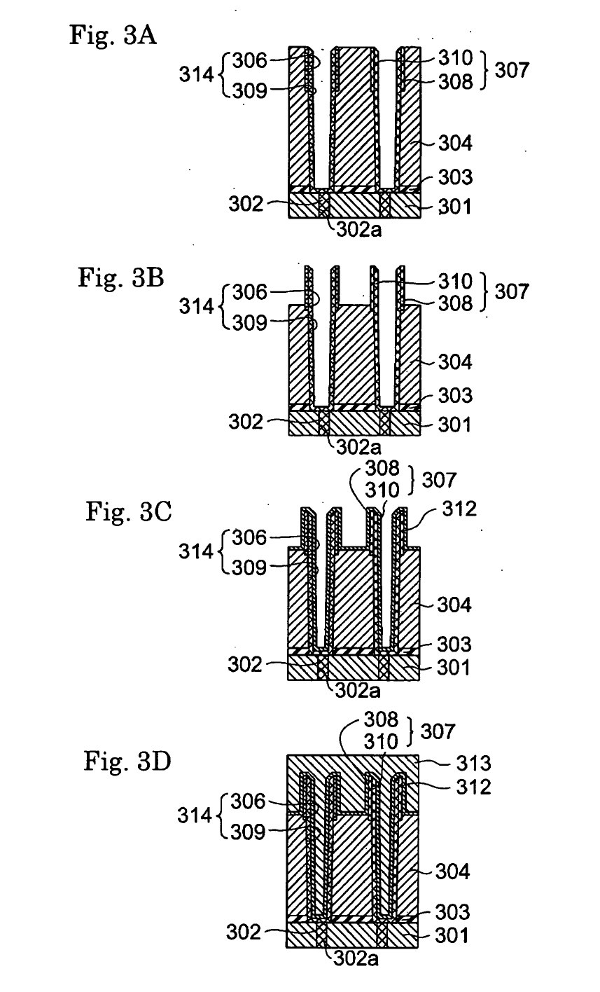

FIGS. 3A to 3D show consecutive steps of a fabrication process of a first modification modified from the above embodiment. This process is also directed to forming the DRAM device of FIG. 1. The step shown in FIG. 3A corresponds to the step of FIG. 2H, wherein the bottom electrodes 307 are formed on the sidewall of the deep-holes 314.

Subsequent to the step of FIG. 3A, the third interlevel dielectric film 304 in the peripheral circuit area 100B is covered with a photoresist mask. Thereafter, the top portion of the interlevel dielectric film 304 outside the bottom electrodes 307 is removed using a hydrofluoric acid so that the bottom edge of the sidewall conductive film 308 is not exposed from the etched third interlevel dielectric film 304, as shown in FIG. 3B. In other words, the most part of the sidewall conductive film 308 is exposed from the third interlevel dielectric film 304.

Thereafter, as shown in FIG. 3C, the dielectric film 312 is formed on the entire surface, followed by depositing the top electrode 313 made of titanium nitride. The thickness of the top electrode 313 is determined so that the entire surface including the internal of the sidewall conductive film 308 and the gap between adjacent sidewall conductive films 308 is filled with the top electrode 313, as shown in FIG. 3D. For example, if the deep-holes 314 have a minor axis of 180 nm, a thickness of 50 nm for the titanium nitride will be sufficient for filling the internal of the sidewall conductive films 308 and the gap between adjacent sidewall conductive films 308.

In the first modification, the opposing area in which the top electrode 313 opposes each of the bottom electrodes 307 is larger compared to the opposing area in the above embodiment because the top electrode 313 opposes the bottom electrodes 307 inside and outside the bottom electrodes 307 or deep-holes 314 in the first modification. In the first modification, the bottom electrodes 307 have a larger mechanical strength because the deep-holes 314 are free from the bowing shape and thus the bottom electrodes 307 have a superior vertical sidewall. Thus, during deposition of the top electrode 313, an air gap is not formed in the internal or external of the cylindrical bottom electrodes 307, whereby the resultant capacitor has a larger mechanical strength. This increases the product yield of the DRAM devices, which would be reduced by the leakage current caused by the mechanical damage within the capacitor. The two-layer structure of the bottom electrodes 307 also increases the mechanical strength of the bottom electrodes 307.

If the silicon film 309 in the bottom electrodes 307 has a smaller thickness in the first modification, hydrofluoric acid may be diffused through the bottom electrodes 307 toward the third interlevel dielectric film 304 or the contact plugs 302 at the bottom of the deep-holes 314 during etching of the third interlevel dielectric film 304. This may incur an undesired etching of the third interlevel dielectric film 304 or contact plugs 302 at the bottom of the deep-holes 314. For avoiding this etching, the deep-holes 314 may preferably be filled with a filling material during the etching by the hydrofluoric acid.

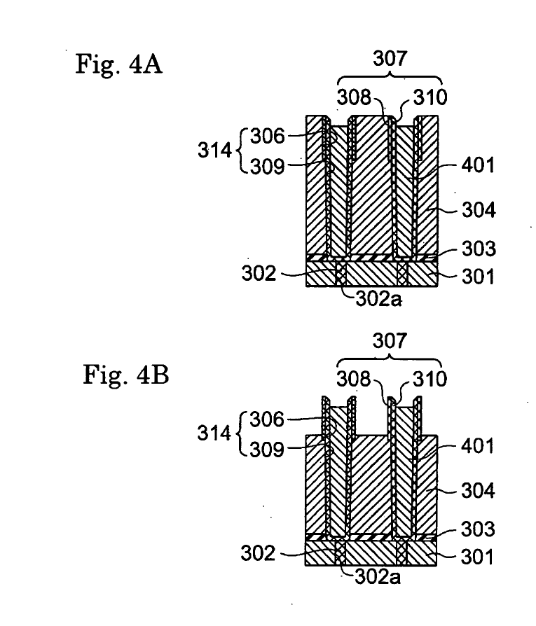

A second modification from the above modification is such that the deep-holes are filled with a filling material during etching of the third interlevel dielectric film 304, as described above. As shown in FIG. 4A, the deep-holes 314 are filled with the filling material 401 subsequent to the step shown in FIG. 3A. Then, the top portion of the third interlevel dielectric film 304 is removed using hydrofluoric acid, as shown in FIG. 4B. The filling material 401 is then removed as by oxygen plasma to obtain the structure shown in FIG. 3B. The other process of the second modification is similar to that of the first modification.

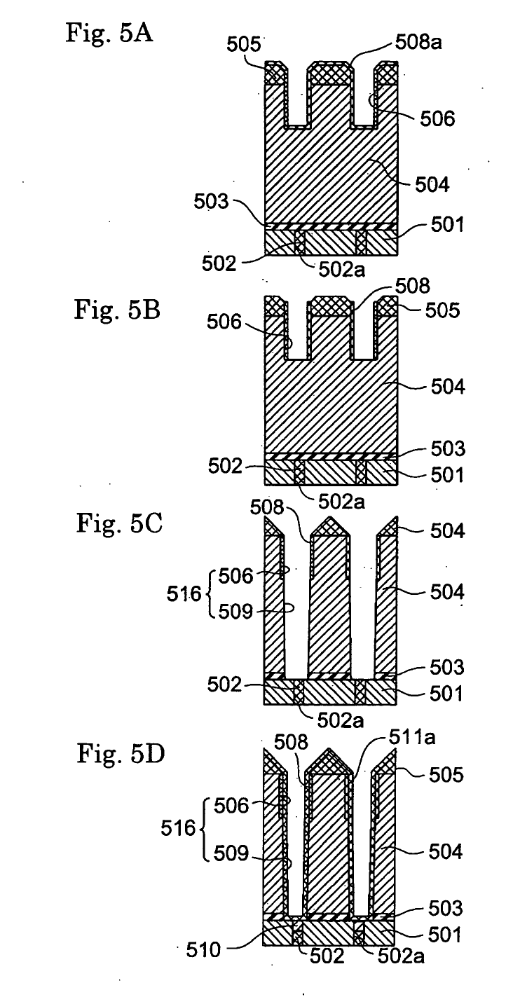

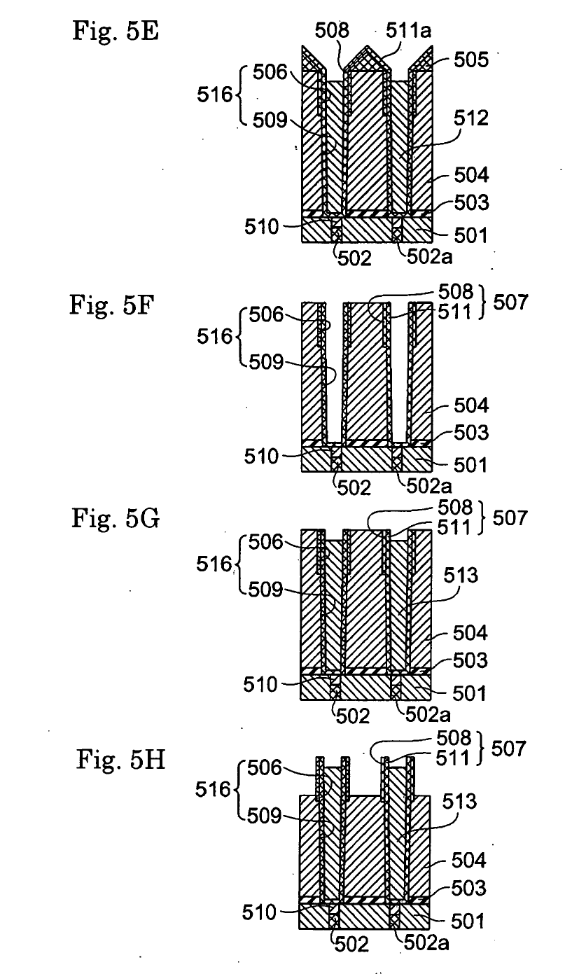

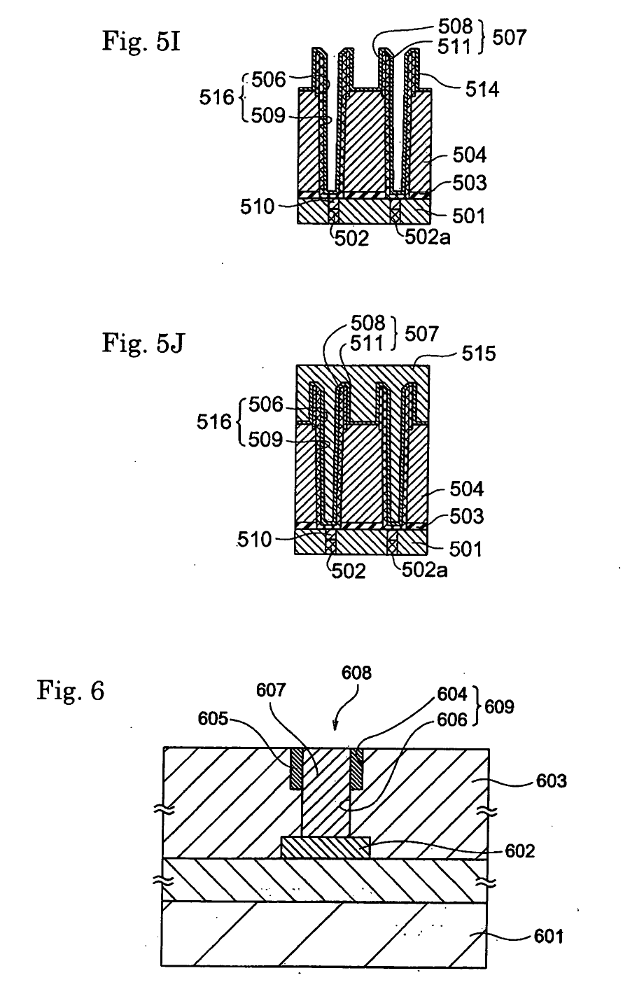

FIGS. 5A to 5J show consecutive steps of a fabrication process according to a third embodiment of the present invention. The capacitors manufactured by the present embodiment have a MIM (metal-insulator-metal) structure in contrast to the MIS (metal-insulator-silicon) structure manufactured by the second embodiment. More specifically, the bottom electrode of the capacitor is made of titanium nitride, which has a higher resistance against dry etching using a fluorine-based gas and thus is suited to the sidewall conductive film. The process itself of the third embodiment is basically similar to that of the second embodiment.

Underlying transistors each including a source, a drain and a gate electrode is formed on a silicon substrate, followed by forming a first interlevel dielectric film on the transistors and the silicon substrate, similarly to the second embodiment. Subsequently, a second interlevel dielectric film 501 is formed on the first interlevel dielectric film, followed by forming contact-holes 502a in the second interlevel dielectric film 501.

Contact plugs 502 made of silicon and filling the contact-holes 502a are then formed, similarly to the second embodiment, followed by forming a silicon nitride film 503 and a 3000-nm-thick third interlevel dielectric film 504 made of silicon dioxide. Thereafter, a hard mask 505 having openings therein is formed on the third interlevel dielectric film 504, followed by forming first holes 506 having a depth of around 1000 nm by using a mixed gas including C₅F₈, Ar and O₂ at a pressure of 100 mTorr and a plasma power of 1500 watts. Thereafter, a surface cleaning process is performed, and a 20-nm-thick first titanium nitride film 508a is deposited using a CVD technique, as shown in FIG. 5A. The first titanium nitride film 508a is deposited using a source gas including TiCl₄ and NH₃ at a temperature of 500 degrees C.

Thereafter, as shown in FIG. 5B, a portion of the titanium nitride film on the bottom of the first holes 506 is removed by a dry etching using a mixed gas including Cl₂ and BCl₃, to thereby leave cylindrical sidewall titanium nitride films 508 on the sidewall of the first holes 506. Titanium nitride is efficiently etched by a dry etching process using a chlorine-based gas. The dry etching uses a pressure of 10 mTorr and a plasma power of 100 watts. A surface cleaning process is then conducted, if necessary, and the portion of the third interlevel dielectric film 504 and the silicon nitride film 503 exposed from the bottom of the first holes 506 is removed using dry etching to form second holes 509 each extending from the first hole 506, as shown in FIG. 5C. This etching uses a fluorocarbon-based gas as in the case of the first holes 506. The first and second holes 506 and 509 thus combined configure deep-holes 516.

Thereafter, surface cleaning is performed so as not to melt the titanium nitride film 508a, followed by removing a natural oxide film having a thickness of around 1 nm from the surface of the contact plugs 502 by using a hydrofluoric-acid-containing solution. Thereafter, a titanium silicide film 510 is formed on the vicinity of the top of the contact plugs 502. The titanium silicide film 510 may be formed using a TiCl₄ gas alone for reducing the contact resistance between the silicon of the contact plug 52 and the titanium nitride of the bottom electrode. A 20-nm-thick second titanium nitride film 511a is subsequently deposited on the titanium silicide film 510 by a CVD process using the same chamber, as shown in FIG. 5D. It is to be noted that a metal or metal compound used for the bottom electrodes allows the contact plugs 502 to be formed from titanium nitride or tungsten, for example. In addition, the step-deposition technique as described before may be employed for depositing the titanium nitride film.

Thereafter, as shown in FIG. 5E, the deep-holes 516 are filled with a filling material 512. Thereafter, the second titanium nitride film 511a and hard mask 505 on the third interlevel dielectric film 504 are removed in a single dry etching step using chlorine-based plasma. Thus, the bottom electrodes 507 are obtained each having the sidewall conductive film 508 and an inner conductive film 511.

Thereafter, as shown in FIG. 5F, the filling material 512 is removed using oxygen plasma or an organic acid such as phenol-alkyl-benzene-sulfonate. Use of an organic acid prevents oxidation of the surface of the titanium nitride film, thereby reducing the leakage current.

Thereafter, as shown in FIG. 5G, the entire surface of the peripheral circuit area 100B is covered with a photoresist mask, and the deep-holes 516 are filled with a filling material 513 such as resist. Thereafter, as shown in FIG. 5H, the top portion of the third interlevel dielectric film 504 is removed by wet etching using hydrofluoric acid, thereby exposing the top outer surface of the bottom electrodes 516.

Thereafter, the filling material 512 is removed similarly to the second embodiment, as shown in FIG. 51, and surface cleaning is performed, if necessary. A step-deposition process is then conducted to deposit a 6-nm-thick dielectric film 514 made of aluminum oxide on the entire surface of the memory cell area. The dielectric film 514 may additionally include hafnium oxide film etc. The dielectric film 514 may have a two-layer structure including an aluminum oxide film having a thickness of around 3 to 4 nm, and a hafnium oxide film having a thickness of around 3 to 4 nm and overlying or underlying the aluminum oxide film. The dielectric film 514 may have a three-layer structure including, from the bottom, an aluminum oxide film having a thickness of 2 to 3 nm, a hafnium oxide film having a thickness of 3 to 4 nm, and another aluminum oxide film having a thickness of 1 to 2 nm. The large dielectric constant of the hafnium oxide film allows the resultant capacitors to have a higher capacitance.

Thereafter, a top electrode 515 made of titanium nitride is formed by deposition to complete cell capacitors having a pseudo-crown structure, as shown in FIG. 5J. Other known steps are performed to complete a DRAM device of FIG. 1. In an alternative, the dielectric film and top electrode may be formed directly after the step of FIG. 5F.

In the third embodiment of the present invention, since the titanium nitride film is scarcely etched by fluorine-based plasma during forming the second holes 509, a bowing shape is not formed in the sidewall of the deep-holes 516.

It is known that the bottom electrodes including a silicon film suffer from a natural oxide film having a thickness of around 1 nm. In contrast, the titanium nitride film is free from the natural oxide film having a lower dielectric constant. Thus, the resultant capacitors have a higher capacitance by about 30% compared to the capacitors having a silicon film in the bottom electrodes.

In addition, since the titanium nitride film has a lower resistance than the silicon film, the bottom electrodes have a smaller thickness and thus the capacitors formed in the deep-holes have a higher capacitance due to the area in which the bottom electrode opposes the top electrode.

The small thickness of the bottom electrodes provides a smaller ratio for the thickness of the bottom electrodes to the minor axis of the deep-holes, which is less than 10%, for example, and thus provides a sufficient space for forming the capacitors in the deep-holes. In this respect, the minor axis of the deep-holes may be 250 nm or may be reduced down to around 100 nm, which is the minimum dimension obtained by the current etching technique. On the other hand, the HSG structure used in the DRAM device heretofore has a thickness of around 80 nm at the minimum.

In manufacture of the pseudo-crown structure of the capacitor, the strength of the bottom electrodes is sometimes critical because the bottom electrodes protrude upward from the associated dielectric film at a stage of the fabrication. The bottom electrodes of the present embodiment have a higher mechanical strength and thus solve such a problem without an increase of the thickness thereof.

In the above embodiment, both the sidewall conductive film and inner conductive film are made of titanium nitride. However, these conductive films may be made of another metal or metallic compound, and may be made of different materials. For example, the sidewall conductive film may be made of silicon for assuring a higher mechanical strength, whereas the inner conductive film may be made of a metal or metallic compound, which has a lower electric resistance. Such a structure allows both a high mechanical strength and a lower resistance, or a high mechanical strength and a smaller thickness. 2. The material for the conductive film may be selected from the group consisting of polysilicon, tungsten, titanium, ruthenium, and a compound including at least one of these elements.

For assuring the advantage of the present invention, 256 mega-bit DRAM devices were manufactured as final products by using the methods of the second embodiment, first modification and the conventional technique. The DRAM devices thus manufactured were subjected to a refreshing characteristic test, wherein all the memory cells were first set at data “0” and the number of memory cells which had lost the data “0” is counted after a time length of 500 milli-seconds elapsed since the setting.

The DRAM device manufactured by the conventional method exhibited several tens of thousands to several hundreds of thousands of the memory cells which had lost the data. On the other hand, the DRAM devices manufactured by the second embodiment and the first modification exhibited only several hundreds of the memory cells which had lost the data. This range of failed memory cells may be recovered in a product by using a known redundancy cell technique. Thus, it was confirmed that the present invention could improve the product yield of the DRAM devices.

FIG. 6 shows a semiconductor device according to a fourth embodiment of the present invention. The principle of the method for forming the deep-hole capacitor can be applied to forming a long contact plug in a semiconductor device. This process for forming a contact plug is similar to the process as described heretofore except that this process does not include the step of forming the inner cylindrical conductive film and the capacitor insulator film.

More specifically, as shown in FIG. 6, the method for forming contact plugs includes the steps of forming an insulator film 603 on an interconnect pattern 602 overlying a semiconductor substrate 601; etching the insulator film 603 to form therein first holes 604 having a depth smaller than a thickness of the insulator film 603; forming cylindrical first conductive films 605 on a sidewall of the first holes 604; etching the insulator film 603 at a bottom of the first holes 604 by using the first conductive films 605 as a mask to form second hole 606s each extending from the first hole 604, the second holes 606 exposing therethrough the interconnect pattern 602; and forming second conductive films 607 within the cylindrical first conductive films 605 and the second holes 606 to form contact plugs 608 in contact with the interconnect pattern 602.

The resultant semiconductor device includes a semiconductor substrate 601; an insulator film 603 overlying the semiconductor substrate 601 and having contact-holes 609 therein; and contact plugs 608 each received in the contact-hole 609 and including a plurality of conductive layers 605 and 607, the conductive layers 605 including a first cylindrical conductive layer 605 in contact with a sidewall of the contact-hole 609 and a second conductive layer 607 received in the cylindrical first conductive layer 605, the second conductive layer 605 configuring a bottom portion of each of the contact plugs 608. The bottom of the contact plugs 609 is in contact with the interconnect pattern 602. The insulator film 603 may have any number of insulator layers. The interconnect pattern 602 underlying the insulator film 602 may be another contact plug.

Since the above embodiments are described only for examples, the present invention is not limited to the above embodiments and various modifications or alterations can be easily made therefrom by those skilled in the art without departing from the scope of the present invention.

What is claimed is:

1. A semiconductor device comprising:
a semiconductor substrate;
a first insulator film overlying said semiconductor substrate and having a deep-hole therein;
a capacitor including a cylindrical first electrode received in said deep-hole and having a cylindrical sidewall and a bottom portion, a capacitor insulator film formed on said first electrode, and a second electrode opposing said first electrode; and
a contact plug connected to said bottom portion of said first electrode, wherein:
said first electrode includes a plurality of conductive layers including a first conductive layer and a second conductive layer covering said first conductive layer, said second conductive layer configuring said bottom portion being in contact with said contact plug.

2. The semiconductor device according to claim 1, wherein said plurality of conductive layers are made of a common conductive material

3. The semiconductor device according to claim 2, wherein said common conductive material is selected from the group consisting of polysilicon, tungsten, titanium, ruthenium, and a compound including at least one of these elements.

4. The semiconductor device according to claim 1, wherein at least two of said plurality of conductive layers are made of different conductive materials.

5. The semiconductor device according to claim 4, wherein each of said different conductive materials is selected from the group consisting of polysilicon, tungsten, titanium, ruthenium and a compound including at least one of these elements.

6. The semiconductor device according to claim 1, wherein said cylindrical sidewall has a cross-section of an ellipse having a minor axis of 100 to 250 nm and a total thickness of equal to or less than 10% of said minor axis.

7. The semiconductor device according to claim 1, wherein said cylindrical sidewall has a cross-section of an ellipse and a length equal to or longer than 10 times a minor axis of said ellipse.

8. A method for manufacturing a semiconductor device comprising the steps of:
forming a first insulator film overlying a semiconductor substrate;
forming a contact plug penetrating said first insulator film;
forming a second insulator film on said first insulator film and said contact plug;
etching said second insulator film to form therein a first hole aligned with said contact plug, said first hole having a depth smaller than a thickness of said second insulator film;
forming a first conductive film on a sidewall of said first hole;
etching said second insulator film at a bottom of said first hole by using said first conductive film as a mask to form a second hole extending from said first hole, said second hole exposing therethrough a top of said contact plug;
depositing a second conductive film on said first conductive film, a sidewall of said second hole and said top of said contact plug, to thereby form a first electrode having a cylindrical sidewall and a bottom portion;
forming an insulator film on said first electrode within said first and second holes; and
forming a second electrode on said insulator film to oppose said first electrode.

9. The method according to claim 8, further comprising, between said second conductive film depositing step and said insulator film forming step, the steps of filling said first and second holes with a filling material, and forming a protecting film on a top surface of said second insulator film.

10. The method according to claim 8, wherein said first conducive film and said second conductive film are made of a common conductive material.

11. The method according to claim 10, wherein said common conductive material is selected from the group consisting of polysilicon, tungsten, titanium, ruthenium and a compound including at least one of these elements.

12. The method according to claim 8, wherein at least two of said plurality of conductive layers are made of different conductive materials.

13. The method according to claim 12, wherein each of said different conductive materials is selected from the group consisting of polysilicon, tungsten, titanium, ruthenium and a compound including at least one of these elements.

14. The method according to claim 8, wherein said cylindrical sidewall has a cross-section of an ellipse having a minor axis of 100 to 250 nm and a thickness of equal to or less than 10% of said minor axis.

15. The method according to claim 8, wherein said cylindrical sidewall has a cross-section of an ellipse and a length equal to or longer than 10 times a minor axis of said ellipse.

16. A semiconductor device comprising:
a semiconductor substrate;
an insulator film overlying said semiconductor substrate and having a contact-hole therein; and
a contact plug received in said contact-hole and including a plurality of conductive layers, said conductive layers including a first cylindrical conductive layer in contact with a sidewall of said contact-hole and a second conductive layer received in said cylindrical first conductive layer, said second conductive layer configuring a bottom portion of said contact plug.

17. A method for manufacturing a semiconductor device comprising the steps of:
forming an interconnect pattern overlying a substrate;
forming an insulator film on said interconnect pattern;
etching said insulator film to form therein a first hole having a depth smaller than a thickness of said first insulator film;
forming a cylindrical first conductive film on a sidewall of said first hole;
etching said insulator film at a bottom of said first hole by using said first conductive film as a mask to form a second hole extending from said first hole, said second hole exposing therethrough said interconnect pattern; and
forming a second conductive film within said cylindrical first conductive film and said second hole to form a contact plug in contact with said interconnect pattern.
